(19) United States
(12) Patent Application Publication
(10) Pub. No.: US 2015/0221346 A1
(43) Pub. Date: Aug. 6, 2015

(54) AREA EFFICIENT MULTIPORT BITCELL

(71) Applicant: QUALCOMM Incorporated, San Diego, CA (US)

(72) Inventors: Rakesh VATTIKONDA, San Diego, CA (US); Frederick NGURE, San Diego, CA (US); Changho JUNG, San Diego, CA (US)

(73) Assignee: QUALCOMM Incorporated, San Diego, CA (US)

(21) Appl. No.: 14/173,788

(22) Filed: Feb. 5, 2014

(51) Int. Cl. G11C 5/02; G11C 7/00

(52) U.S. Cl. CPC G11C 5/02; G11C 7/00

(57) ABSTRACT

A multiport bitcell apparatus includes a plurality of word lines for enabling writing and reading operations. The word lines include a first set of word lines extending across the bitcell on a first metal layer. The word lines further include a second set of word lines extending across the bitcell on a second metal layer. The word lines further include a third set of word lines extending across the bitcell on both the first metal layer and the second metal layer. The third set of word lines may include a first word line that extends on a first metal track and a second metal track, and a second word line that extends on the second metal track and a third metal track. The first metal layer may be an M2 layer and the second metal layer may be an M3 layer.

### BACKGROUND

1. Field

The present disclosure relates generally to a layout construction, and more particularly, to an area efficient multiport bitcell.

2. Background

Multiport bitcells occupy a substantial area in a system on a chip (SOC). Accordingly, area efficient multiport bitcells are needed for reducing the size of an SOC.

### SUMMARY

In an aspect of the disclosure, a multiport bitcell apparatus includes a plurality of word lines for enabling writing and reading operations. The word lines include a first set of word lines extending across the bitcell on a first metal layer, a second set of word lines extending across the bitcell on a second metal layer, and a third set of word lines extending across the bitcell on both the first metal layer and the second metal layer. The third set of word lines may include a first word line that extends on a first metal track and a second metal track, and a second word line that extends on the second metal track and a third metal track. The first metal layer may be a metal 2 (M2) layer and the second metal layer may be a metal 3 (M3) layer.

### BRIEF DESCRIPTION OF THE DRAWINGS

FIG. 1 is a diagram illustrating a multiport bitcell.

FIG. 2 is a diagram illustrating a configuration with a plurality of multiport bitcells.

FIGS. 3A, 3B are diagrams illustrating a layout of local and global word lines.

FIG. 4 is a diagram illustrating widths and pitches of the horizontally extending metal and poly interconnects within a bitcell.

FIG. 5A is a diagram illustrating an exemplary layout of word lines on the M2 layer for a bitcell.

FIG. 5B is a diagram illustrating an exemplary layout of word lines on the M3 layer for a bitcell.

FIG. 6A is a diagram illustrating an exemplary layout of word lines on the M2 layer for two adjacent bitcells.

FIG. 6B is a diagram illustrating an exemplary layout of word lines on both the M2 and M3 layers for two adjacent bitcells.

FIG. 7 is a diagram illustrating exemplary widths and pitches of the horizontally extending metal and poly interconnects within a 6-port bitcell.

FIG. 8 is a flow chart of an exemplary method of a multiport bitcell apparatus including a plurality of word lines for enabling writing and reading operations.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Apparatuses and methods will be described in the following detailed description and may be illustrated in the accompanying drawings by various blocks, modules, components, circuits, steps, processes, algorithms, elements, etc.

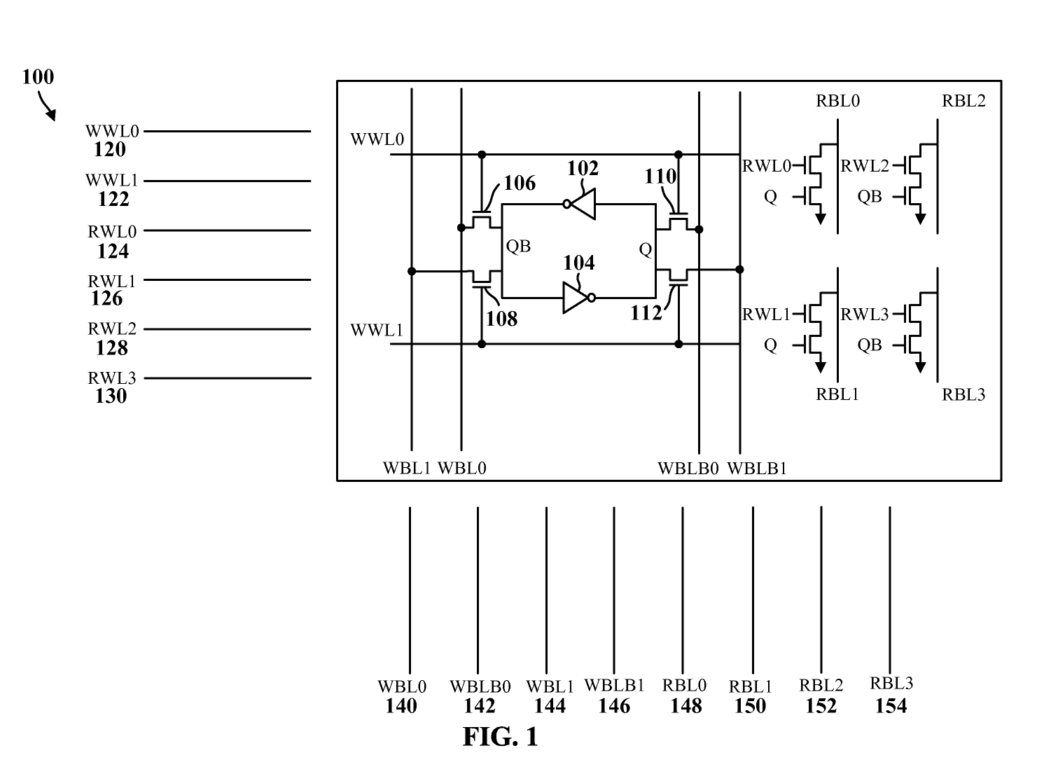

FIG. 1 is a diagram 100 illustrating a multiport bitcell. Specifically, the multiport bitcell is a 6-port bitcell with two write ports and four read ports. The multiport bitcell includes 16 transistors. The multiport bitcell includes inverters 102, 104 and pass gates 106, 108, 110, 112. The multiport bitcell includes six local word lines: two local write word lines WWL0 120 and WWL1 122, and four local read word lines RWL0 124, RWL1 126, RWL2 128, and RWL3 130. The multiport bitcell further includes eight bit lines WBL0 140, WBLB0 142, WBL1 144, WBLB1 146, RBL0 148, RBL1 150, RBL2 152, and RBL3 154. The local write word line WWL0 120 concurrently enables a bit to be written to the bitcell from the write bit line WBL0 140 and the write bit line WBLB0 142. The bit on the write bit line WBLB0 142 is inverted from the bit on the write bit line WBL0 140. The local write word line WWL1 122 concurrently enables a bit to be written to the bitcell from the write bit line WBL1 144 and the write bit line WBLB1 146. The bit on the write bit line WBLB1 146 is inverted from the bit on the write bit line WBL1 144. The local read word lines RWL0 124, RWL1 126, RWL2 128, RWL3 130 enable the stored bit from the Q output and inverted QB output to be read from the read bit lines RBL0 148, RBL1 150, RBL2 152, and RBL3 154, respectively. As shown in FIG. 1, the eight bitlines 140-154 extend vertically across the bitcell, and the six local word lines 120-130 extend horizontally across the bitcell.

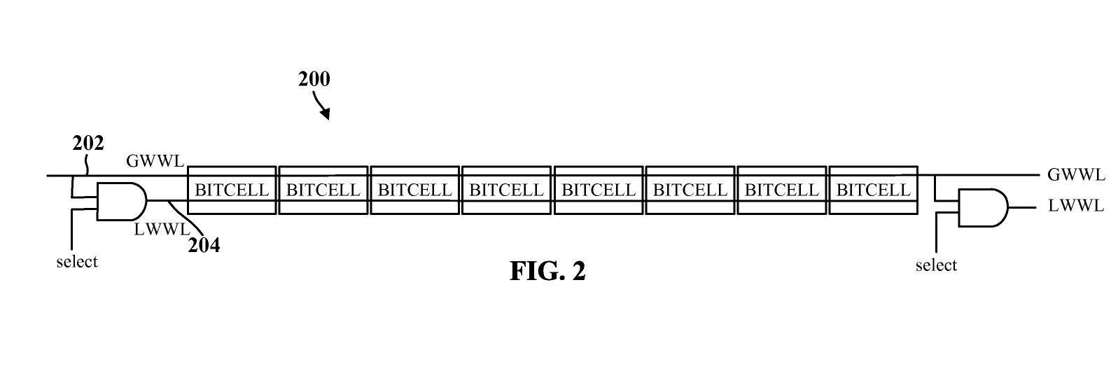

FIG. 2 is a diagram 200 illustrating a configuration with a plurality of multiport bitcells. As shown in FIG. 2, the plurality of multiport bitcells include a set of global write word lines GWWL 202 for byte-write operations and a set of local write word lines LWWL 204 for bit-write operations. The set of local write word lines LWWL 204 includes the write word lines WWL0 120 and WWL1 122. The set of global write word lines may include two global write word lines GWWL0 and GWWL1. Each of the global write word lines GWWL0 and GWWL1 may also extend horizontally across a bitcell along with the six local word lines WWL0 120, WWL1 122, RWL0 124, RWL1 126, RWL2 128, and RWL3 130. Accordingly, eight word lines may extend horizontally across a bitcell.

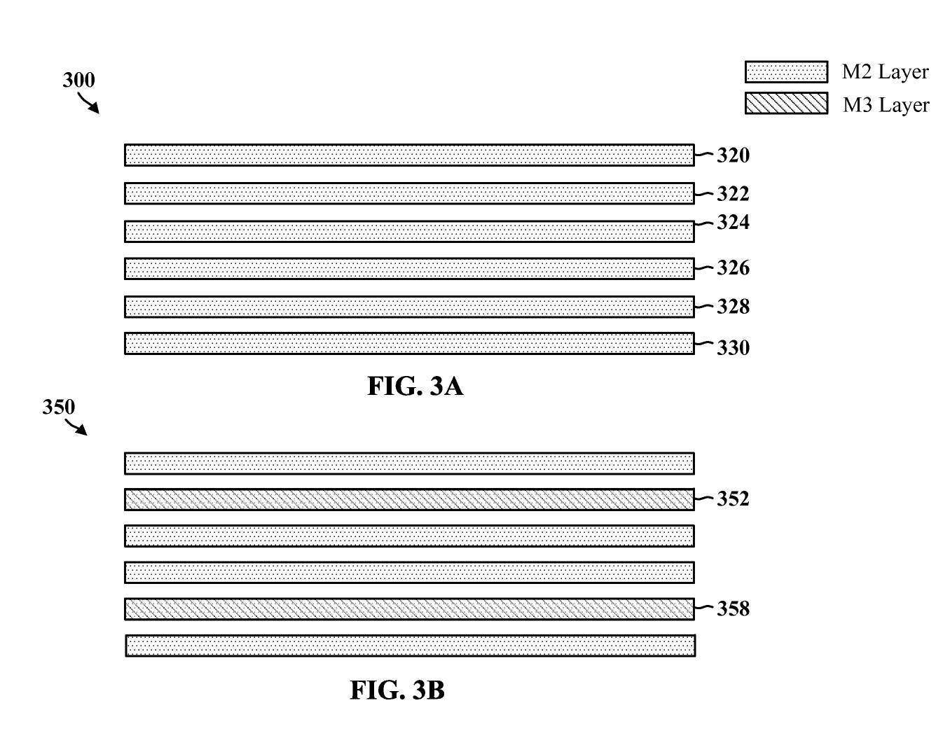

FIGS. 3A, 3B are diagrams 300, 350 illustrating a layout of local and global word lines. As shown in FIG. 3A, the six local word lines WWL0 120, WWL1 122, RWL0 124, RWL1 126, RWL2 128, and RWL3 130 may be implemented with M2 (metal 2) layer interconnects 320, 322, 324, 326, 328, 330, respectively (FIG. 3A shows only the M2 layer interconnects). As shown in FIG. 3B, the two global word lines GWWL0 and GWWL1 may be implemented with M3 (metal 3) layer interconnects 352, 358 (FIG. 3B shows both the M2 layer interconnects and the M3 layer interconnects). The M3 layer interconnects are above the M2 layer interconnects. The M3 layer interconnect 352 extends on the same metal track as the M2 layer interconnect 322, and the M3 layer interconnect 358 extends on the same metal track as the M2 layer interconnect 328.

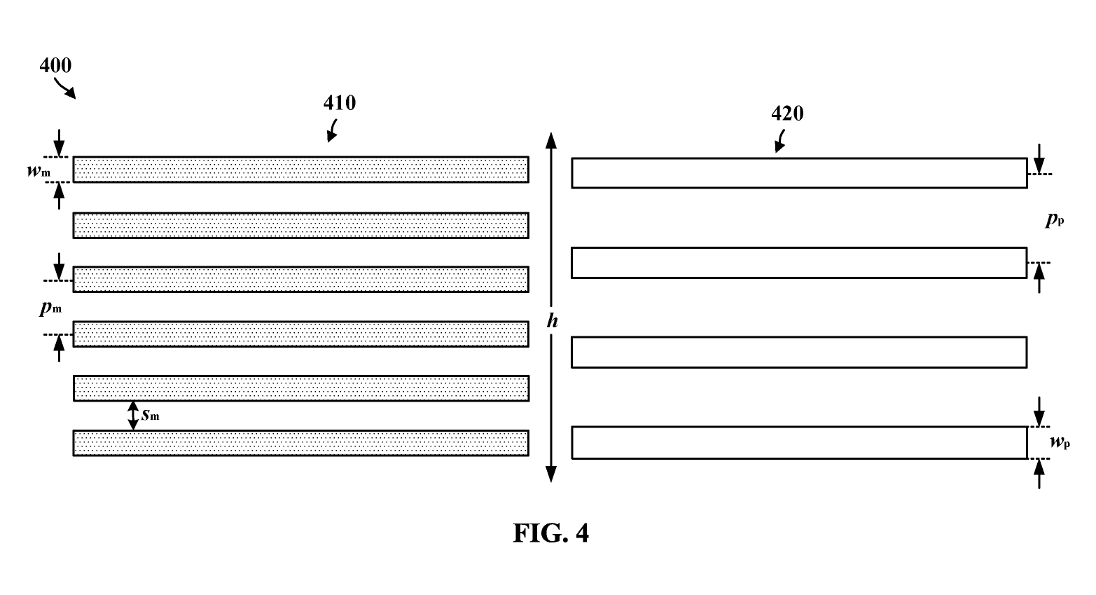

FIG. 4 is a diagram 400 illustrating widths and pitches of the horizontally extending metal interconnects 410 and poly gates 420 within a bitcell. In order to reduce a height h of a bitcell, a minimum metal width wₘ and a minimum metal pitch pₘ may be used for the local word lines. A spacing between the metal interconnects is sₘ. The metal pitch pₘ is equal to sₘ+wₘ. In one example, the minimum metal width wₘ is 32 nm and the minimum metal spacing sₘ is 32 nm. Accordingly, in one example, the minimum metal pitch pₘ is 64 nm. The height h of a bitcell may be determined by the metal pitch. In one example, the height h of a bitcell may be equal to 6pₘ. Assuming the bitcell has four poly (gate) tracks extending horizontally in the bitcell, the poly pitch pₚ may be h/4. In one example, h=384 nm and pₚ=96 nm. A transistor length of each of the 16 transistors in the bitcell may be determined by the poly pitch pₚ. The transistor length is the same as the width wₚ of the poly gates. In one example, the poly width wₚ=26 nm.

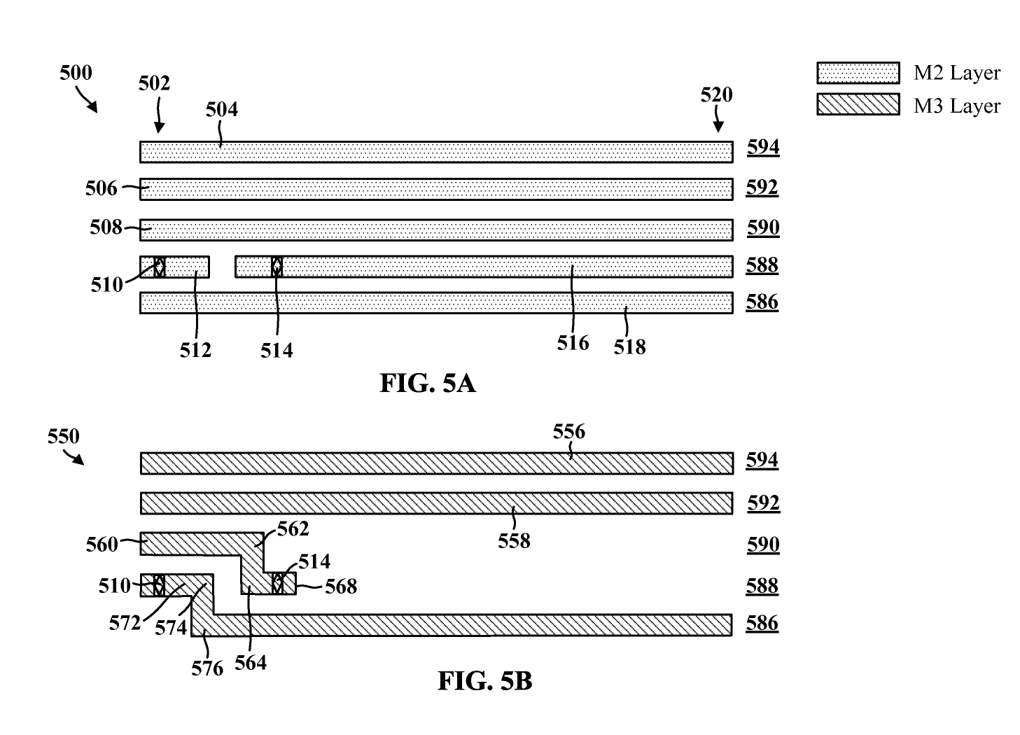

FIG. 5A is a diagram 500 illustrating an exemplary layout of word lines on the M2 layer for a bitcell. FIG. 5B is a diagram 550 illustrating an exemplary layout of word lines on the M3 layer for a bitcell. As shown in FIGS. 5A, 5B, five metal tracks 586, 588, 590, 592, 594 rather than six may be used for the eight word lines. Four local word lines may be implemented with M2 layer interconnects 504, 506, 508, 518. The two global word lines may be implemented with M3 layer interconnects 556, 558. Two of the remaining local word lines may be implemented with both M2 and M3 layer interconnects that shift to different metal tracks. One of the two local word lines may be implemented with the M2 layer interconnect 512 on the metal track 588 and the M3 layer interconnect 572 on the metal tracks 586 and 588. Another of the two local word lines may be implemented with the M2 layer interconnect 516 on the metal track 588 and the M3 layer interconnect 560 on the metal tracks 588 and 590.

Specifically, a multiport bitcell apparatus includes a plurality of word lines WWL0 120, WWL1 122, RWL0 124, RWL1 126, RWL2 128, RWL3 130, GWWL0, and GWWL1 for enabling writing and reading operations. The word lines include a first set of word lines through interconnects 504, 506, 508, 518 that extend across the bitcell on a first metal layer. The first metal layer may be an M2 layer. The word lines further include a second set of word lines through interconnects 556, 558 that extend across the bitcell on a second metal layer. The second metal layer may be an M3 layer. The word lines further include a third set of word lines extending across the bitcell on both the first metal layer and the second metal layer.

The third set of word lines includes a first word line through interconnects 512, 572 that extends on a first metal track 586 and a second metal track 588, and a second word line through interconnects 516, 560 that extends on the second metal track 588 and a third metal track 590. The first word line includes a first interconnect 572 on the second metal layer that extends on the second metal track 588 from a first side 502 of the bitcell to a first point 574 between the first side 502 of the bitcell and a second side 520 of the bitcell opposite the first side 502 of the bitcell, from the first point 574 on the second metal track 588 to a second point 576 on the first metal track 586 between the first side 502 of the bitcell and the second side 520 of the bitcell, and from the second point 576 on the first metal track 586 to the second side 520 of the bitcell on the first metal track 586. The first word line further includes a second interconnect 512 on the first metal layer that extends on the second metal track 588 to the first side 502 of the bitcell. The first word line further includes a via 510 at the first side 502 of the bitcell on the second metal track 588 that connects the first interconnect 572 to the second interconnect 512. The second word line includes a third interconnect 560 on the second metal layer that extends on the third metal track 590 from the first side 502 of the bitcell to a third point 562 between the first side 502 of the bitcell and the second side 520 of the bitcell opposite the first side 502 of the bitcell, from the third point 562 on the third metal track 590 to a fourth point 564 on the second metal track 588 between the first side 502 of the bitcell and the second side 520 of the bitcell, and from the fourth point 564 on the second metal track 588 to a fifth point 568 on the second metal track 588 between the first side 502 of the bitcell and the second side 520 of the bitcell. The second word line further includes a fourth interconnect 516 on the first metal layer that extends past the fifth point 568 on the second metal track 588 to the second side 520 of the bitcell on the second metal track 588. The second word line further includes a second via 514 between the fourth point 564 and the fifth point 568 on the second metal track 588 that connects the third interconnect 560 to the fourth interconnect 516.

The first point 574 on the second metal track 588 is between the via 510 on the second metal track 588 and the fourth point 564 on the second metal track 588. The first set of word lines includes a fifth interconnect 518 on the first metal layer that extends on the first metal track 586 from the first side 502 of the bitcell to the second side 520 of the bitcell, a sixth interconnect 508 on the first metal layer that extends on the third metal track 590 from the first side 502 of the bitcell to the second side 520 of the bitcell, a seventh interconnect 506 on the first metal layer that extends on a fourth metal track 592 from the first side 502 of the bitcell to the second side 520 of the bitcell, and an eighth interconnect 504 on the first metal layer that extends on a fifth metal track 594 from the first side 502 of the bitcell to the second side 520 of the bitcell. The second set of word lines includes a ninth interconnect 558 on the second metal layer that extends on the fourth metal track 592 from the first side 502 of the bitcell to the second side 520 of the bitcell, and a tenth interconnect 556 on the second metal layer that extends on the fifth metal track 594 from the first side 502 of the bitcell to the second side 520 of the bitcell.

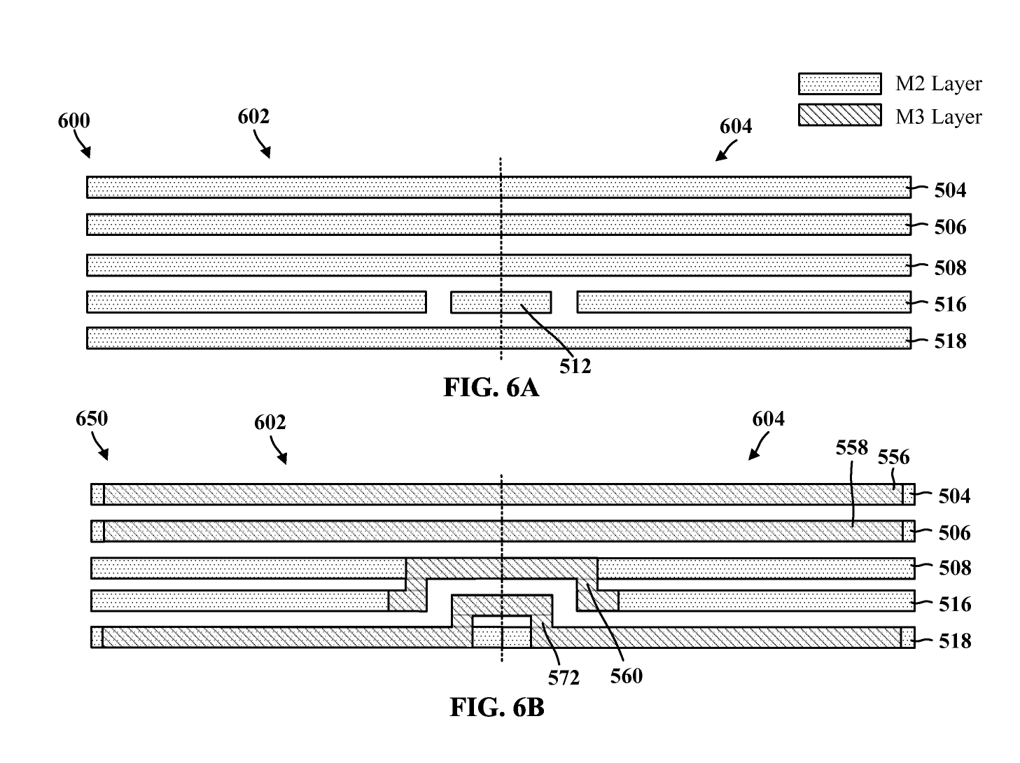

FIG. 6A is a diagram 600 illustrating an exemplary layout of word lines on the M2 layer for two adjacent bitcells. FIG. 6B is a diagram 650 illustrating an exemplary layout of word lines on both the M2 and M3 layers for two adjacent bitcells. As shown in FIGS. 6A, 6B, the exemplary layout as discussed in relation to FIGS. 5A, 5B may be used with adjacent bitcells, including a first bitcell 602 and a second bitcell 604. The layout of the first bitcell 602 is a mirror image of the layout of the second bitcell 604.

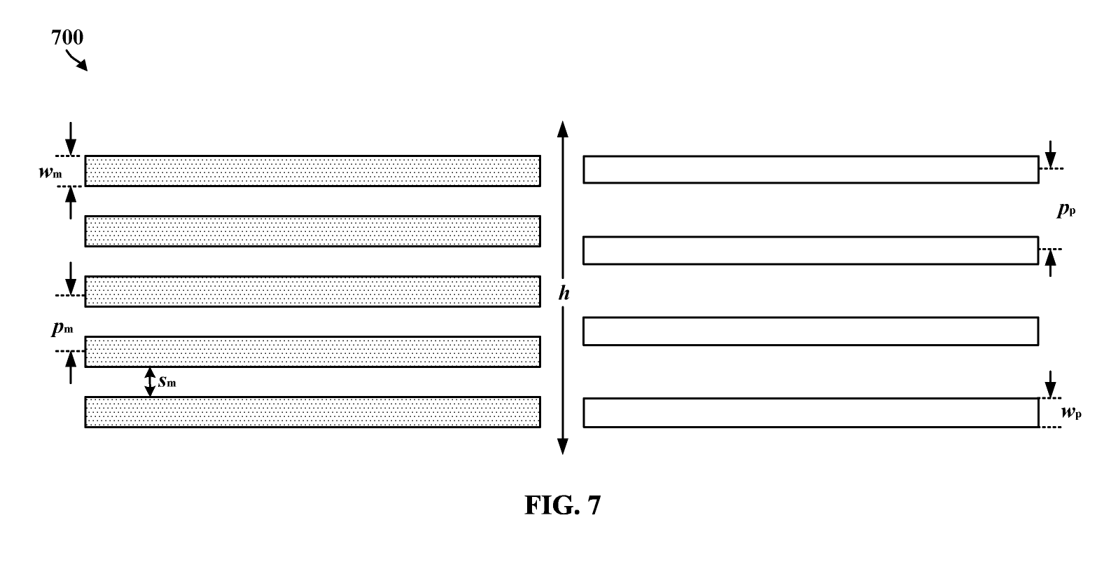

FIG. 7 is a diagram 700 illustrating exemplary widths and pitches of the horizontally extending metal and poly interconnects within a 6-port bitcell. With the exemplary layout, the poly pitch pₚ may be reduced to 90 nm and the height h of a bitcell may be determined based on the poly pitch pₚ rather than the metal pitch mₚ. In such a configuration, the height h of a bitcell is equal to 4pₚ. With pₚ=90 nm, h=360 nm. As five metal tracks are used, the metal pitch mₚ may be equal to h/5=72 nm. Assuming the same minimum spacing as discussed in relation to FIG. 4, the metal width wₘ may be equal to 72 nm−32 nm=40 nm. With a poly pitch pₚ=90 nm, the poly width wₚ may be equal to 20 nm. Accordingly, the transistor length of each of the 16 transistors in the 6-port bitcell may be equal to 20 nm. With the exemplary layout of FIGS. 5A, 5B, the height h of the bitcell has shrunk from 384 nm to 360 nm, providing an area savings. In addition, the reduced transistor length of 20 nm as opposed to 26 nm provides for faster access times for the read ports. Further, the increased metal width wₘ of 40 nm as opposed to 32 nm reduces the resistance of the metal interconnects and provides faster access times. The reduced transistor length and metal resistance provides a speed improvement of around 10% for the exemplary 6-port bitcell.

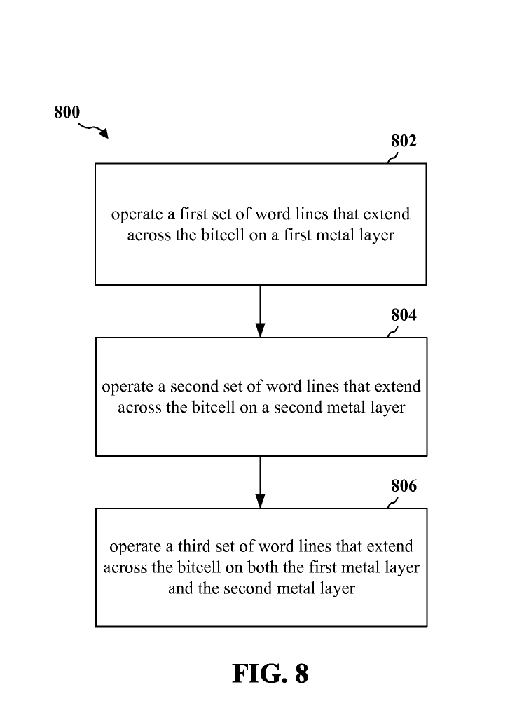

FIG. 8 is a flow chart 800 of an exemplary method of a multiport bitcell apparatus including a plurality of word lines for enabling writing and reading operations. The method is performed by a multiport bitcell apparatus. In the method/apparatus, “to operate” a word line can mean “conducting a current through” the word line. In step 802, the apparatus operates a first set of word lines that extend across the bitcell on a first metal layer. In step 804, the apparatus operates a second set of word lines that extend across the bitcell on a second metal layer. In step 806, the apparatus operates a third set of word lines that extend across the bitcell on both the first metal layer and the second metal layer. The first metal layer may be an M2 layer and the second metal layer may be an M3 layer. As discussed supra in relation to FIGS. 5A, 5B, the third set of word lines may include a first word line that extends on a first metal track and a second metal track, and a second word line that extends on the second metal track and a third metal track.

A multiport bitcell apparatus includes a plurality of word lines for enabling writing and reading operations. The apparatus includes means for operating a first set of word lines that extend across the bitcell on a first metal layer, means for operating a second set of word lines that extend across the bitcell on a second metal layer, and means for operating a third set of word lines that extend across the bitcell on both the first metal layer and the second metal layer. The means for operating a first set of word lines is the first set of word lines, the means for operating a second set of word lines is the second set of word lines, and the means for operating a third set of word lines in the third set of word lines.

The third set of word lines may include a first word line that extends on a first metal track and a second metal track, and a second word line that extends on the second metal track and a third metal track. The first word line may include a first interconnect on the second metal layer that extends on the second metal track from a first side of the bitcell to a first point between the first side of the bitcell and a second side of the bitcell opposite the first side of the bitcell, from the first point on the second metal track to a second point on the first metal track between the first side of the bitcell and the second side of the bitcell, and from the second point on the first metal track to the second side of the bitcell on the first metal track. The first word line may further include a second interconnect on the first metal layer that extends on the second metal track to the first side of the bitcell. The first word line may further include a via at the first side of the bitcell on the second metal track that connects the first interconnect to the second interconnect. The second word line may include a third interconnect on the second metal layer that extends on the third metal track from the first side of the bitcell to a third point between the first side of the bitcell and the second side of the bitcell opposite the first side of the bitcell, from the third point on the third metal track to a fourth point on the second metal track between the first side of the bitcell and the second side of the bitcell, and from the fourth point on the second metal track to a fifth point on the second metal track between the first side of the bitcell and the second side of the bitcell. The second word line may further include a fourth interconnect on the first metal layer that extends past the fifth point on the second metal track to the second side of the bitcell on the second metal track. The second word line may further include a second via between the fourth point and the fifth point on the second metal track that connects the third interconnect to the fourth interconnect. The first point on the second metal track may be between the via on the second metal track and the fourth point on the second metal track. The first set of word lines may include a fifth interconnect on the first metal layer extending on the first metal track from the first side of the bitcell to the second side of the bitcell, a sixth interconnect on the first metal layer extending on the third metal track from the first side of the bitcell to the second side of the bitcell, a seventh interconnect on the first metal layer extending on a fourth metal track from the first side of the bitcell to the second side of the bitcell, and an eighth interconnect on the first metal layer extending on a fifth metal track from the first side of the bitcell to the second side of the bitcell. The second set of word lines may include a ninth interconnect on the second metal layer extending on the fourth metal track from the first side of the bitcell to the second side of the bitcell, and a tenth interconnect on the second metal layer extending on the fifth metal track from the first side of the bitcell to the second side of the bitcell.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A multiport bitcell apparatus including a plurality of word lines for enabling writing and reading operations, the word lines comprising:
a first set of word lines extending across the bitcell on a first metal layer;
a second set of word lines extending across the bitcell on a second metal layer; and
a third set of word lines extending across the bitcell on both the first metal layer and the second metal layer.

2. The apparatus of claim 1, wherein the first metal layer is a metal 2 (M2) layer and the second metal layer is a metal 3 (M3) layer.

3. The apparatus of claim 1, wherein the third set of word lines comprises a first word line that extends on a first metal track and a second metal track, and a second word line that extends on the second metal track and a third metal track.

4. The apparatus of claim 3, wherein the first word line comprises:
a first interconnect on the second metal layer that extends on the second metal track from a first side of the bitcell to a first point between the first side of the bitcell and a second side of the bitcell opposite the first side of the bitcell, from said first point on the second metal track to a second point on the first metal track between the first side of the bitcell and the second side of the bitcell, and from said second point on the first metal track to the second side of the bitcell on the first metal track;
a second interconnect on the first metal layer that extends on the second metal track to the first side of the bitcell;
a via at the first side of the bitcell on the second metal track that connects the first interconnect to the second interconnect.

5. The apparatus of claim 4, wherein the second word line comprises:
a third interconnect on the second metal layer that extends on the third metal track from the first side of the bitcell to a third point between the first side of the bitcell and the second side of the bitcell opposite the first side of the bitcell, from said third point on the third metal track to a fourth point on the second metal track between the first side of the bitcell and the second side of the bitcell, and from said fourth point on the second metal track to a fifth point on the second metal track between the first side of the bitcell and the second side of the bitcell;
a fourth interconnect on the first metal layer that extends past said fifth point on the second metal track to the second side of the bitcell on the second metal track;
a second via between said fourth point and said fifth point on the second metal track that connects the third interconnect to the fourth interconnect.

6. The apparatus of claim 5, wherein said first point on the second metal track is between the via on the second metal track and said fourth point on the second metal track.

7. The apparatus of claim 5, wherein the first set of word lines comprises a fifth interconnect on the first metal layer extending on the first metal track from the first side of the bitcell to the second side of the bitcell, a sixth interconnect on the first metal layer extending on the third metal track from the first side of the bitcell to the second side of the bitcell, a seventh interconnect on the first metal layer extending on a fourth metal track from the first side of the bitcell to the second side of the bitcell, and an eighth interconnect on the first metal layer extending on a fifth metal track from the first side of the bitcell to the second side of the bitcell.

8. The apparatus of claim 7, wherein the second set of word lines comprises a ninth interconnect on the second metal layer extending on the fourth metal track from the first side of the bitcell to the second side of the bitcell, and a tenth interconnect on the second metal layer extending on the fifth metal track from the first side of the bitcell to the second side of the bitcell.

9. The apparatus of claim 1, wherein the plurality of word lines comprises eight word lines.

10. The apparatus of claim 1, wherein the multiport bitcell is a 6-port bitcell.

11. A method of operating a multiport bitcell apparatus including a plurality of word lines for enabling writing and reading operations, comprising:
operating a first set of word lines that extend across the bitcell on a first metal layer;
operating a second set of word lines that extend across the bitcell on a second metal layer; and
operating a third set of word lines that extend across the bitcell on both the first metal layer and the second metal layer.

12. The method of claim 11, wherein the first metal layer is a metal 2 (M2) layer and the second metal layer is a metal 3 (M3) layer.

13. The method of claim 11, wherein the third set of word lines comprises a first word line that extends on a first metal track and a second metal track, and a second word line that extends on the second metal track and a third metal track.

14. The method of claim 13, wherein the first word line comprises:
a first interconnect on the second metal layer that extends on the second metal track from a first side of the bitcell to a first point between the first side of the bitcell and a second side of the bitcell opposite the first side of the bitcell, from said first point on the second metal track to a second point on the first metal track between the first side of the bitcell and the second side of the bitcell, and from said second point on the first metal track to the second side of the bitcell on the first metal track;
a second interconnect on the first metal layer that extends on the second metal track to the first side of the bitcell;
a via at the first side of the bitcell on the second metal track that connects the first interconnect to the second interconnect.

15. The method of claim 14, wherein the second word line comprises:
a third interconnect on the second metal layer that extends on the third metal track from the first side of the bitcell to a third point between the first side of the bitcell and the second side of the bitcell opposite the first side of the bitcell, from said third point on the third metal track to a fourth point on the second metal track between the first side of the bitcell and the second side of the bitcell, and from said fourth point on the second metal track to a fifth point on the second metal track between the first side of the bitcell and the second side of the bitcell;
a fourth interconnect on the first metal layer that extends past said fifth point on the second metal track to the second side of the bitcell on the second metal track;
a second via between said fourth point and said fifth point on the second metal track that connects the third interconnect to the fourth interconnect.

16. The method of claim 15, wherein said first point on the second metal track is between the via on the second metal track and said fourth point on the second metal track.

17. The method of claim 15, wherein the first set of word lines comprises a fifth interconnect on the first metal layer extending on the first metal track from the first side of the bitcell to the second side of the bitcell, a sixth interconnect on the first metal layer extending on the third metal track from the first side of the bitcell to the second side of the bitcell, a seventh interconnect on the first metal layer extending on a fourth metal track from the first side of the bitcell to the second side of the bitcell, and an eighth interconnect on the first metal layer extending on a fifth metal track from the first side of the bitcell to the second side of the bitcell.

18. The method of claim 17, wherein the second set of word lines comprises a ninth interconnect on the second metal layer extending on the fourth metal track from the first side of the bitcell to the second side of the bitcell, and a tenth interconnect on the second metal layer extending on the fifth metal track from the first side of the bitcell to the second side of the bitcell.

19. The method of claim 11, wherein the plurality of word lines comprises eight word lines.

20. A multiport bitcell apparatus including a plurality of word lines for enabling writing and reading operations, comprising:
means for operating a first set of word lines that extend across the bitcell on a first metal layer;
means for operating a second set of word lines that extend across the bitcell on a second metal layer; and
means for operating a third set of word lines that extend across the bitcell on both the first metal layer and the second metal layer.
